(19) United States
(12) Patent Application Publication
(10) Pub. No.: US 2008/0230260 A1
(43) Pub. Date: Sep. 25, 2008

(54) Flip-chip substrate

(75) Inventor: Chao-Wen SHIH, Hsinchu (TW)

Correspondence Address: BACON & THOMAS, PLLC, 625 SLATERS LANE, FOURTH FLOOR, ALEXANDRIA, VA, 22314-1176, US

(73) Assignee: Phoenix Precision Technology Corporation, Hsinchu (TW)

(21) Appl. No.: 12/076,678

(22) Filed: Mar. 21, 2008

(30) Foreign Application Priority Data
Mar. 23, 2007 (TW) 096110114

(51) Int. Cl. H05K 1/09

(52) U.S. Cl. 174/257

(57) ABSTRACT

A flip-chip substrate is disclosed, which comprises a core substrate including an aluminum oxide substrate and a first circuit layer, wherein the aluminum oxide substrate has a top surface, a bottom surface, and a plurality of conductive through holes, the conductive through holes connect the top surface and the bottom surface the first circuit layer disposed on the top surface and the bottom surface and electrically connects to the conductive through holes; and a built-up structure disposed on the top surface and the bottom surface and electrically connecting to the first circuit layer. Moreover, the conductive through holes are formed by forming plural through holes through electrolyzing, and then forming a first seed layer and a first metal layer inside the through holes. Therefore, the problem of substrate warpage can be prevented, and the wiring density of the flip-chip substrate can be improved.

### BACKGROUND OF THE INVENTION

1. Field of the Invention

The present invention relates to a flip-chip substrate, and, more particularly, to a flip-chip substrate capable of avoiding substrate warpage.

2. Description of Related Art

As the electronic industry develops rapidly, research moves towards electronic devices with multifunctions and high efficiency. Hence, circuit boards with many active and passive components and circuit connections thereon have been transformed from double-layered boards to multiple-layered boards so that the requirements such as integration and miniaturization in semiconductor packaging substrate can be met. Furthermore, interlayer connection technique is also applied in this field to expand circuit layout space in a limited circuit board and to meet the demand of the application of high-density integrated circuits.

For manufacturing conventional semiconductor packaging structures, a chip is mounted on the top surface of a substrate first, and then connected thereto by wire bonding. Alternatively, the chip is connected with the substrate by flip chip technique. Subsequently, solder balls are disposed on the bottom surface of the substrate and electrically connected to a printed circuit board.

FIGS. 1A to 1E show a process for manufacturing a conventional flip-chip substrate. In FIG. 1A, a core board 11 is prepared first. The core board 11 has to be made of an insulating material. So far, Bismaleimide Triazine (BT) Resin is used as the material of the core board 11 in the industry. As shown in FIG. 1B, a plurality of through holes 11a penetrating the whole cross-section of the core board 11 is then formed. Generally, the through holes 11a are formed by a mechanical method such as drilling. With reference to FIG. 1C, a seed layer (not shown) and a metal layer 12 are subsequently formed on the surface of the core board 11 and the inner surface of the through holes 11a in sequence. Then, the through holes 11a are filled with a resin 13. With regard to FIG. 1D, a patterned resist layer 14 is formed on the surface of the core board 11 next. Referring to FIG. I E, the metal layer 12 and the seed layer (not shown) which is not covered by the patterned resist layer 14 is removed by etching, and the patterned resist layer 14 is then removed after completing the steps illustrated above. Therefore, the patterned metal layer 12 located on the top and bottom surface of the core board 11 functions as circuit layers 12a of a flip-chip substrate. Alternatively, the patterned metal layer 12 located on the inner surface of the through holes 11a functions to electrically connect the circuit layers 12a.

Referring to FIG. 1F, two built-up structures 91 are respectively formed on the top and bottom sides of the core board 11 to obtain a multiple-layered flip-chip substrate. Each built-up structure 91 primarily comprises at least one dielectric layer 91a and at least one metal layer 91b stacked alternately. The process of forming the built-up structure is well known in this field and, therefore, detailed steps of a built-up process are not described herein.

Subsequently, solder masks 41 having a plurality of openings are formed on the surface of the built-up structures 91. Accordingly, partial metal layers 91b of the built-up structure 91 are exposed in the openings to function as conductive pads. Finally, pluralities of solder bumps 42 are formed on the conductive pads to complete a flip-chip substrate. Moreover, the solder bumps 42 at different sides of the flip-chip substrate have different diameters. The solder bumps 42 at the bottom side of the flip-chip substrate are bigger in diameter so as to act as solder balls which are electrically connected to a printed circuit board. The solder bumps 42 at the top side of the flip-chip substrate are smaller in diameter so as to electrically connect to chips.

So far in the application in industry, the material of the core board 11 is mostly made of BT resin, and the material of the dielectric layer 91a is mostly made of ABF (Ajinomoto build-up film) resin. Unfortunately, the coefficient of thermal expansion (CTE) of BT resin and ABF resin are different. The CET difference causes substrate warpage to the flip-chip substrate such that the yield and the reliability are both reduced.

In addition, the through holes of the flip-chip substrate are generally formed by drilling. Due to the technique limit of drilling, the diameter of the through holes of the flip-chip substrate cannot be lower than 50 μm so that the density of the circuit layout cannot be improved.

Accordingly, it is desirable to provide a new material suitable for manufacturing a flip-chip substrate to prevent substrate warpage, to reduce the diameter of through holes, and to increase the yield of flip-chip substrate.

### SUMMARY OF THE INVENTION

The present invention provides a flip-chip substrate using aluminum oxide, which has excellent thermal properties and mechanical properties (for example, the Young's modulus of aluminum oxide is 380 Gpa), as the material of the core board to prevent substrate warpage, to achieve a fine-patterned circuit layout, and to improve the dimensional stability of the flip-chip substrate.

In addition, the through holes of the flip-chip substrate using aluminum oxide as the core board's material can be formed by electrolysis without drilling, or other related conventional method for forming through holes in a core board. Accordingly, in the flip-chip substrate of the present invention, the width of the through holes can be made at the level of 100 μm to 10 nm, so as to be advantageous for forming a fine-patterned circuit layout and increasing the density of the circuit layout.

One aspect of the present invention provides a flip-chip substrate comprising: a core board including an aluminum oxide board and a first circuit layer, wherein the aluminum oxide board has a top surface, a bottom surface, and a plurality of conductive through holes that are disposed through a plurality of through holes penetrating the aluminum oxide board by electrolysis and disposing a first seed layer and a first metal layer on the inner surface of the through holes, the conductive through holes electrically connect the top surface and the bottom surface of the aluminum oxide board, and the circuit layer electrically connecting to the conductive through holes is disposed on the top surface and the bottom surface of the aluminum oxide board and a built-up structure disposed on at least one side of the aluminum oxide board and electrically connecting to the first circuit layer.

In the flip-chip substrate of the present invention, the structure of the conductive through holes is not limited as long as the conductive through holes electrically connects with the first circuit layer disposed on the top and bottom surfaces of the aluminum oxide board. In one preferred embodiment, the conductive through holes comprise the first seed layer formed on the inner surface of the through holes and the first metal layer fills the through holes. In another preferred embodiment, the conductive through holes comprise the first seed layer formed on the inner surface of the through holes, the first metal layer formed inside the through holes, and the filler fills the through holes. Moreover, the material of the first metal layer is not limited. Preferably, the first metal layer is made of copper. Also, the material of the first seed layer is not limited. Preferably, the first seed layer is made of a material selected from the group consisting of copper, tin, nickel, chromium, titanium, copper-chromium alloy and tin-lead alloy.

In the flip-chip substrate of the present invention, the structure of the circuit layer is not limited. In one preferred embodiment, the circuit layer is composed of the first metal layer and the first seed layer.

In the flip-chip substrate of the present invention, the built-up structure can be any built-up structure suitable for applying to a flip-chip substrate. Preferably, the built-up structure comprises a plurality of dielectric layers, a plurality of second circuit layers and a plurality of conductive vias, wherein the second circuit layer is stacked on the dielectric layers, the conductive vias penetrate the dielectric layers to connect with the second circuit layers and the first circuit layer and the second circuit layers under the dielectric layers. In addition, the second circuit layers are composed of a second metal layer and a second seed layer. The material of the second metal layer is not limited. Preferably, the second metal layer is made of copper. Also, the material of the second seed layer is not limited. Preferably, the second seed layer is selected from a group consisting of copper, tin, nickel, chromium, titanium, copper-chromium alloy and tin-lead alloy.

In addition, the flip-chip substrate of the present invention can further comprise a solder mask formed on the surface of the built-up structure, wherein the solder mask has a plurality of openings to expose part of the second circuit layers as conductive pads. The material of the solder mask is not limited. Preferably, the solder mask is made of a solder resist material with photoimagable polymer.

Additionally, the flip-chip substrate of the present invention can further comprise a plurality of solder bumps formed on the conductive pads of the built-up structure, selectively.

Another aspect of the present invention provides a method for manufacturing a flip-chip substrate using aluminum oxide as a core board's material so as to prevent substrate warpage. Importantly, the through holes of the core board are formed by electrolysis so that the diameter of the through holes can be reduced and the density of the circuit layout can be improved. The method for manufacturing a flip-chip substrate comprises the following steps: (A) providing an aluminum oxide board having a top surface, a bottom surface and a plurality of through holes that are formed by electrolysis and connecting with the top surface and bottom surface of the aluminum oxide board;

(B) forming a first seed layer on the top surface of the aluminum oxide board, the bottom surface of the aluminum oxide board, and the inner surface of the through holes;

(C) forming a patterned resist layer on the top surface and the bottom surface of the aluminum oxide board, wherein the patterned resist layer has a plurality of openings corresponding to the through holes;

(D) electroplating a first metal layer in the openings and the through holes;

(E) removing the patterned resist layer and the first seed layer covered by the patterned resist layer to form a first circuit layer and a plurality of conductive through holes, wherein the first circuit layer electrically connects to the conductive through holes; and

(F) forming a built-up structure on at least one side of the aluminum oxide board, wherein the built-up structure electrically connects to the first circuit layer.

In the method of the present invention for manufacturing a flip-chip substrate, the steps for forming the built-up structure are not limited. Preferably, the built-up structure is formed by the following steps:

forming a dielectric layer on at least one side of the aluminum oxide board, wherein the dielectric layers have a plurality of vias corresponding to the first circuit layer;

forming a second seed layer and a patterned resist layer on the dielectric layers and in the vias in sequence, wherein the patterned resist layer has a plurality of openings corresponding to the vias;

electroplating a second metal layer in the openings; and

removing the patterned resist layer and the second seed layer covered by the patterned resist layer.

Moreover, the method in the present invention for manufacturing a flip-chip substrate can further comprise a step (G) for forming a solder mask on the surface of the built-up structure after the step (F), wherein the solder mask has a plurality of openings exposing the second metal layer as conductive pads, and a step (H) for forming a plurality of solder bumps on the conductive pads after the step (G).

In the method of the present invention, the steps for forming the aluminum oxide board provided in step (A) are not limited. In one preferred embodiment, the aluminum oxide board provided in step (A) is formed by the following steps:

providing an aluminum oxide board;

forming a patterned resist layer on the top surface and the bottom surface of the aluminum oxide board;

dissolving the aluminum oxide board uncovered by the patterned resist layer by electrolysis to form the through holes, connecting with the top surface and bottom surface of the aluminum oxide board, at the position where the aluminum oxide board is uncovered by the patterned resist layer; and removing the patterned resist layer.

More preferably, the aluminum oxide board can be obtained by oxidizing an aluminum board so as to reduce the production cost, because the aluminum board, which has low price and good processing property, is suitable for mass-production and can be transferred into an aluminum oxide board by a simple method, such as oxidizing.

Therefore, the other preferred embodiment of the aluminum oxide board provided in step (A) is formed by the following steps:

providing an aluminum board;

oxidizing the aluminum board to be an aluminum oxide board;

forming a patterned resist layer on the top surface and the bottom surface of the aluminum oxide board;

dissolving the aluminum oxide board uncovered by the patterned resist layer by electrolysis to form the through holes, connecting with the top surface and bottom surface of the aluminum oxide board, at the position where the aluminum oxide board is uncovered by the patterned resist layer; and removing the patterned resist layer.

Another preferred embodiment of the aluminum oxide board provided in step (A) is formed by the following steps:

providing an aluminum board;

forming a patterned resist layer on the top surface and the bottom surface of the aluminum board;

dissolving the aluminum board uncovered by the patterned resist layer by electrolysis to form the through holes, connecting with the top surface and bottom surface of the aluminum board, at the position where the aluminum board is uncovered by the patterned resist layer; and

removing the patterned resist layer; and

oxidizing the aluminum board to be an aluminum oxide board.

In the above-mentioned steps for forming the aluminum oxide board provided in step (A), the way to oxidize the aluminum board is not limited. Preferably, the aluminum board is oxidized by baking for reducing the producing-cost.

Other objects, advantages, and novel features of the invention will become more apparent from the following detailed description when taken in conjunction with the accompanying drawings.

### BRIEF DESCRIPTION OF THE DRAWINGS

FIGS. 1A to 1F show a process for manufacturing a conventional flip-chip substrate in a cross-sectional view;

FIGS. 2A to 2N show a process for manufacturing a flip-chip substrate in a cross-sectional view according to one preferred embodiment of the present invention;

FIGS. 3A to 3B show a process for manufacturing a flip-chip substrate in a cross-sectional view according to another preferred embodiment of the present invention; and

FIGS. 4A to 4F show a process for manufacturing a flip-chip substrate in a cross-sectional view according to the other preferred embodiment of the present invention.

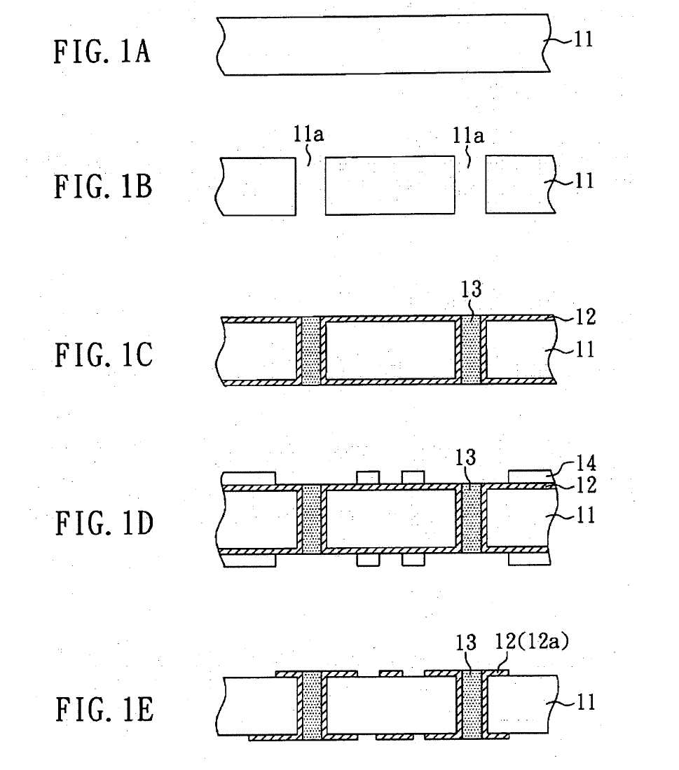

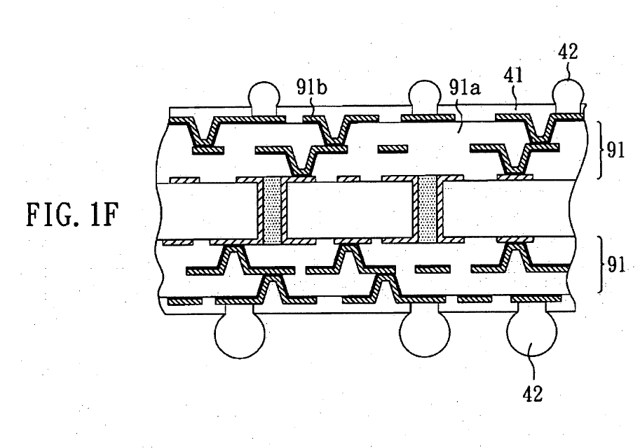

### DETAILED DESCRIPTION OF THE PREFERRED EMBODIMENT

The drawings of the embodiments in the present invention are all simplified charts or views, and only reveal elements relative to the present invention. The elements revealed in the drawings are not necessarily aspects of the practice, and quantity and shape thereof are optionally designed. Further, the design aspect of the elements can be more complex.

### Embodiment 1

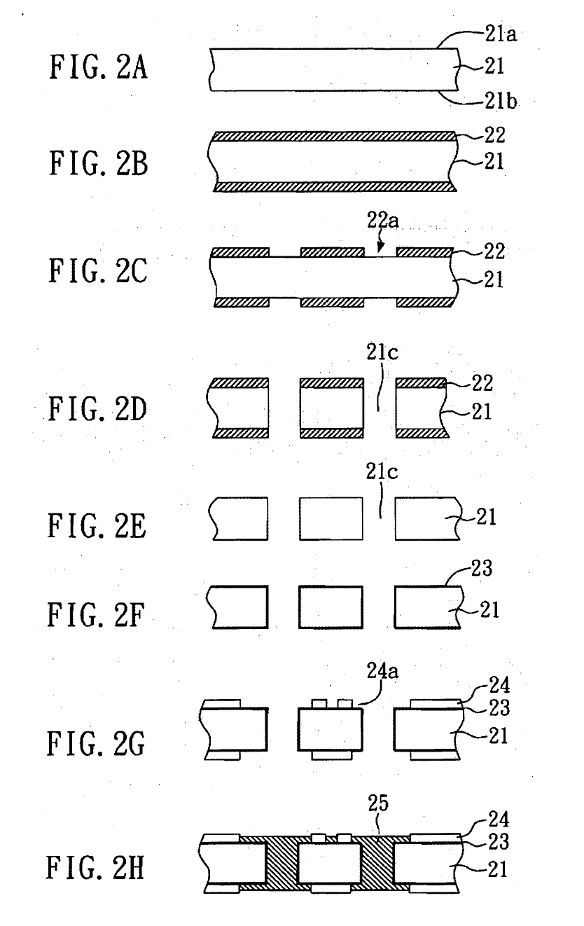

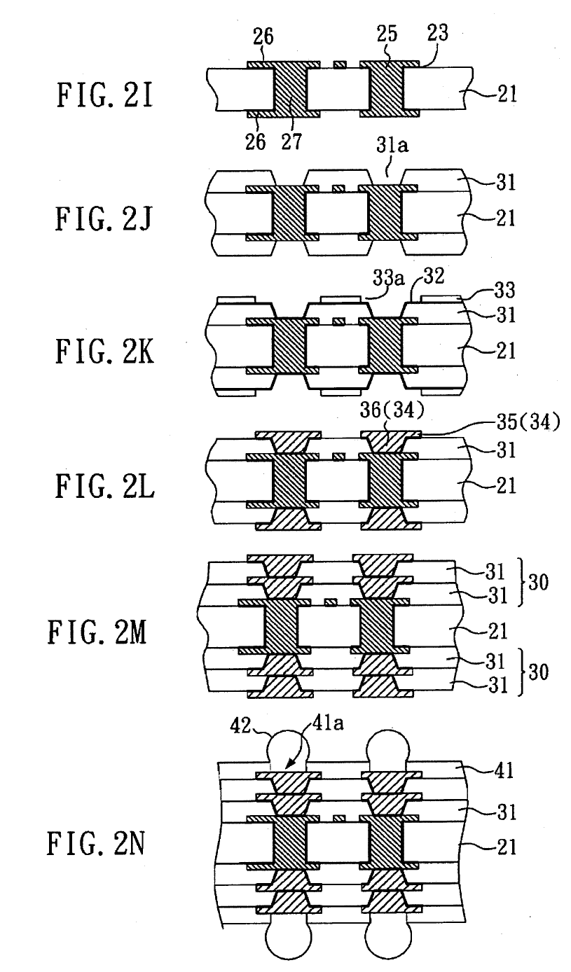

With reference to FIGS. 2A to 2N, there is shown a process flow for manufacturing a flip-chip substrate in a cross-sectional view in the present embodiment.

In FIG. 2A, an aluminum oxide board 21 is provided first as a core board of a flip-chip substrate. Then, a resist layer 22 is formed on the top surface 21a and the bottom surface 21b of the aluminum oxide board 21, as shown in FIG. 2B. The resist layer 22 used in this embodiment is a dry film. Subsequently, a plurality of openings 22a in the resist layer 22 is formed by photolithography, as shown in FIG. 2C.

After completing the above steps, part of the aluminum oxide board 21 not covered by the resist layer 22 is dissolved by electrolysis to form a plurality of through holes 21c, which penetrate the cross-section of the aluminum oxide board 21, as shown in FIG. 2D. Then, with reference to FIG. 2E, the resist layer 22 is removed so that the aluminum oxide board 21 having a plurality of through holes 21 is obtained. In this embodiment, the through holes 21c is located corresponding to each of the openings 22a and formed by electrolysis. Therefore, the diameter of the through holes 21 can achieve a level of 100 μm to 10 nm so as to benefit a fine-patterned circuit layout and increase the density of a circuit layout. On the other hand, the conventional method, in which through holes of a core board of a flip-chip substrate is formed by drilling, has a problem that the diameter of the through holes cannot be lower than 50 μm and the density of the circuit layout cannot be increased due to the technique limit of drilling.

Subsequently, with regard to FIG. 2F, a first seed layer 23 is formed on the surface of the aluminum oxide board 21 and the inner surface of the through holes 21 by electroless plating. In this embodiment, the first seed layer 23 is formed by chemical deposition. Then, referring to FIG. 2G, a patterned resist layer 24 is formed on the top surface 21a and the bottom surface 21b of the aluminum oxide board. The patterned resist layer 24 has a plurality of openings 24a corresponding to the through holes 21c. The patterned resist layer 24 used in this embodiment is a dry film. Further, as shown in FIG. 2H, a first metal layer 25 is formed in each openings 24a by electroplating. The material of the first metal layer used in this embodiment is a copper. Herein, the through holes 21c are filled with the first metal layer 25 (as shown in FIG. 2H). Alternatively, the through holes 21c can be filled with resin as fillers (not shown) while the diameter of the through holes 21c is increased.

Furthermore, referring to FIG. 21, the patterned resist layer 24 and part of the first seed layer 23 not covered by the patterned resist layer 24 are removed so as to obtain a first circuit layer 26 and a plurality of conductive through holes 27. The first circuit layer 26 is disposed on the top surface 21a and bottom surface 21b of the aluminum oxide board 21. In this embodiment, the first circuit layer 26 is a laminate composed of the first metal layer 25 and the first seed layer 23. Besides, the conductive through holes 26, electrically connecting to the first circuit layer 23, penetrate the aluminum oxide board 21 to connect with the top surface 21a and bottom surface 21b of the aluminum oxide board 21. In this embodiment, the conductive through holes 26 are composed of the first seed layer 23 formed on the inner surface of the through holes 21c, and the first metal layer 25 fills the through holes 21c. Alternatively, the conductive through holes 26 can be composed of the first seed layer 23 formed on the inner surface of the through holes 21c, the first metal layer 25 formed on the first seed layer 23, and resin (not shown) fills the through holes 21c as a filler.

After the above-mentioned steps, the aluminum oxide board 21 is processed through a built-up process to form a built-up structure 30 on its top and bottom side, as shown in FIG. 2M. With reference to FIGS. 2J to 2L, the built-up process is illustrated as follows.

At first, as shown in FIG. 2J, a dielectric layer 31 is formed on the top surface 21a and the bottom surface 21b of the aluminum oxide board 21. A plurality of vias 31a is formed in the dielectric layer 31 by means of laser drilling or a photolithographic process, wherein at least one of the vias 31 corresponds to the first circuit layer 26. Note that de-smearing processes must be performed to remove the smears generated in the dielectric layer openings when laser drilling is employed. Herein, the material of the dielectric layer 31 used in this embodiment is at least one material selected from the group consisting of: ABF (Ajinomoto Build-up Film), BT (Bismaleimide Triazine), BCB (Benzocylobutene), Liquid Crystal Polymer, PI (Polyimide), Poly (Phenylene Ether), Poly (tetra-fluoroethylene), Aramide, epoxy and glass fiber. In this embodiment, the material of the dielectric layer 31 is ABF.

Then, referring to FIG. 2K, a second seed layer 32 is formed on the dielectric layer 31 and in each via 31a. Further, a resist layer 33 having a plurality of openings 33a is further formed on the second seed layer 32. The openings 33a of the resist layer 34 are formed by a photolithographic process, and at least one of the openings 33a corresponds to the vias 31 a. In this embodiment, the second seed layer 32 is made of copper.

Subsequently, with regard to FIG. 2L, a second metal layer 34 is formed in each opening 33a. Then, the resist layer 33 and the second seed layer 32 covered by the resist layer 33 are removed so as to form second circuit layers 35 and a plurality of conductive vias 36. The material of the second metal layer 34 used in this embodiment is copper. If needed, the build-up process illustrated in FIGS. 2J to 2L can be repeated to form a multiple-layered built-up structure 30, as shown in FIG. 2M. In FIG. 2M, the second circuit layers 35, composed of the second metal layer 34 and second seed layer 32, are stacked on the dielectric layers 31. Besides, the conductive vias 36 penetrate the dielectric layer 31 to electrically connect with the second circuit layers 35 and the first circuit layer 26 or the second circuit layers 35 under the second circuit layers 35.

Further, with regard to FIG. 2N, a solder mask 41 is formed on the surface of the built-up structure 30. The material of the solder mask 41 used in this embodiment is a solder resist material with photoimagable polymer. Besides, the solder mask 41 has a plurality of openings 41a to expose part of the second metal layer 34 as conductive pads. Finally, plural solder bumps 42 are formed on the conductive pads, and, thus, a flip-chip substrate is complete.

### Embodiment 2

In this embodiment, an aluminum oxide board is obtained by oxidizing an aluminum board for reduce the producing cost, because the aluminum board, which has low price and good processing property, is suitable for mass-producing and can be transformed into an aluminum oxide board by a simple method, such as oxidizing.

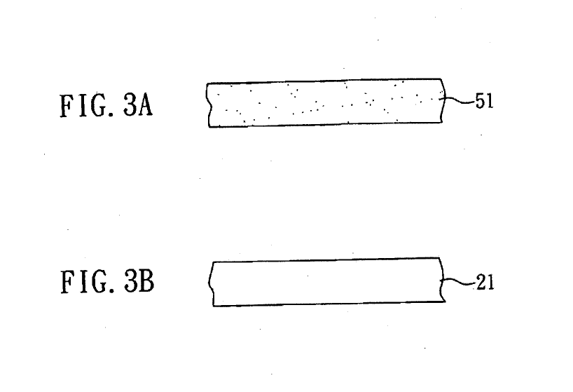

As shown in FIG. 3A, an aluminum board is provided first. Then, with reference to FIG. 3B, the aluminum board 51 is oxidized to be a non-conductive aluminum oxide board 21 by backing in the air. Further, the procedure illustrated in FIGS. 2B to 2N of embodiment 1 is proceeded to obtain a flip-chip substrate. Therefore, detailed steps of the procedure illustrated in FIGS. 2B to 2N are not described herein.

### Embodiment 3

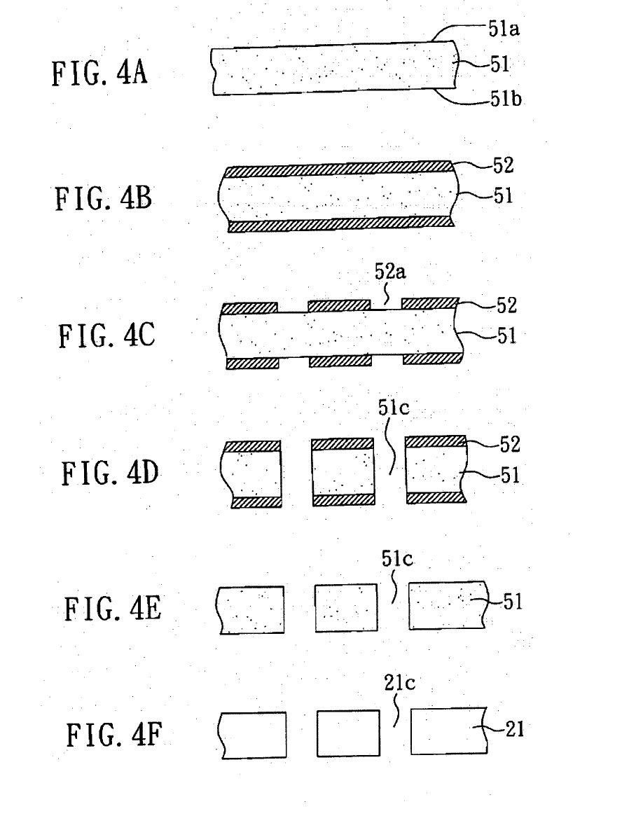

As in embodiment 2, the method for manufacturing a flip-chip substrate of this embodiment is started by providing an aluminum board 51 first, as shown in FIG. 4A.

Then, with regard to FIG. 4B, a resist layer 52 is formed on the top surface 51a and bottom surface 51b of the aluminum board 51. The resist layer 52 used in this embodiment is a dry film. Subsequently, as shown in FIG. 4C, a plurality of openings 52a is formed in the resist layer 52 by development.

After the above steps, referring to FIG. 4D, the aluminum board 51 is electrolyzed to solve part of the aluminum board 51 not covered by the resist layer 52 so as to form a plurality of through holes 51c penetrating the cross-section of the aluminum board 51. Further, as shown in FIG. 4E, the resist layer 52 is removed so that a plurality of through holes 51c is obtained. In this embodiment, the through holes 51c are located corresponding to each of the openings 52a and formed by electrolysis. Therefore, the diameter of the through holes 51 can achieve a level of 100 μm to 10 nm so as to benefit a fine-patterned circuit layout and increase the density of a circuit layout.

Furthermore, as shown in FIG. 4F, the aluminum board 51 is oxidized to be a non-conductive aluminum oxide board 21 by backing in the air. Meanwhile, an aluminum oxide board 21 having plural through holes 21c is obtained. Then, the procedure illustrated in FIGS. 2F to 2N of embodiment 1 is proceeded to obtain a flip-chip substrate. Therefore, detailed steps of the procedure illustrated in FIGS. 2F to 2N are not described herein.

The present invention provides a flip-chip substrate using aluminum oxide, which has excellent thermal properties and mechanical properties, as the material of the core board to prevent substrate warpage, to achieve a fine-patterned circuit layout, and to improve the dimensional stability of the flip-chip substrate.

In addition, the through holes of the flip-chip substrate using aluminum oxide as the core board's material can be formed by electrolysis without drilling, or other related conventional method for forming through holes in a core board. Accordingly, in the flip-chip substrate of the present invention, the width of the through holes can be made at the level of 100 μm to 10 nm, so as to be advantageous for forming a fine-patterned circuit layout and increasing the density of the circuit layout.

Although the present invention has been explained in relation to its preferred embodiment, it is to be understood that many other possible modifications and variations can be made without departing from the scope of the invention as hereinafter claimed.

What is claimed is:

1. A flip-chip substrate comprising:
a core board including an aluminum oxide board and a first circuit layer, wherein the aluminum oxide board has a top surface, a bottom surface, and a plurality of conductive through holes that are disposed through a plurality of through holes penetrating the aluminum oxide board by electrolysis and disposing a first seed layer and a first metal layer on the inner surface of the through holes, the conductive through holes electrically connect the top surface and the bottom surface of the aluminum oxide board, and the circuit layer electrically connecting to the conductive through holes is disposed on the top surface and the bottom surface of the aluminum oxide board; and
a built-up structure disposed on at least one side of the aluminum oxide board and electrically connecting to the first circuit layer.

2. The flip-chip substrate as claimed in claim 1, wherein the conductive through holes comprise the first seed layer formed on the inner surface of the through holes and the first metal layer fills the through holes.

3. The flip-chip substrate as claimed in claim 1, wherein the conductive through holes comprise the first seed layer formed on the inner surface of the through holes, the first metal layer formed inside the through holes, and filler fills the through holes.

4. The flip-chip substrate as claimed in claim 1, wherein the first circuit layer comprises the first metal layer and the first seed layer.

5. The flip-chip substrate as claimed in claim 1, wherein the material of the first metal layer is copper.

6. The flip-chip substrate as claimed in claim 1, wherein the material of the first seed layer is selected from the group consisting of copper, tin, nickel, chromium, titanium, copper-chromium alloy and tin-lead alloy.

7. The flip-chip substrate as claimed in claim 1, wherein the built-up structure comprises a plurality of dielectric layers, a plurality of second circuit layers, and a plurality of conductive vias, in which the second circuit layer is stacked on the dielectric layers, the conductive vias penetrate the dielectric layers to connect with the second circuit layers and the first circuit layer and the second circuit layers under the dielectric layers.

8. The flip-chip substrate as claimed in claim 7, wherein each second circuit layer comprises a second metal layer and a second seed layer.

9. The flip-chip substrate as claimed in claim 7, further comprising a solder mask formed on the surface of the built-up structure, wherein the solder mask has a plurality of openings to expose part of the second circuit layers as conductive pads.

10. The flip-chip substrate as claimed in claim 9, further comprising a plurality of solder bumps formed on the conductive pads of the built-up structure.
